(19) United States
(12) Patent Application Publication
(10) Pub. No.: US 2026/0114255 A1
(43) Pub. Date: Apr. 23, 2026

(54) SEMICONDUCTOR STRUCTURE AND FABRICATION METHOD THEREOF

(71) Applicant: UNITED MICROELECTRONICS CORP., Hsin-Chu City (TW)

(72) Inventors: Da-Jun Lin, Kaohsiung City (TW); Yi-An Shih, Changhua County (TW); Fu-Yu Tsai, Tainan City (TW); Bin-Siang Tsai, Changhua County (TW)

(73) Assignee: UNITED MICROELECTRONICS CORP., Hsin-Chu City (TW)

(21) Appl. No.: 18/938,310

(22) Filed: Nov. 6, 2024

(30) Foreign Application Priority Data
Oct. 21, 2024 (TW) 113139904

(51) Int. Cl. H01L 23/528; H01L 21/762; H01L 21/768; H01L 23/498

(52) U.S. Cl. CPC H10W 20/427; H10P 90/1906; H10P 90/1908; H10W 10/014; H10W 10/061; H10W 10/17; H10W 10/181; H10W 20/076; H10W 70/635

(57) ABSTRACT

A semiconductor structure includes an SOI substrate having a base substrate, a buried oxide layer on the base substrate, and a device layer on the buried oxide layer, a circuit element disposed on the device layer and surrounded by a trench isolation region in the SOI substrate; an etch stop layer disposed around the circuit element; a first dielectric layer disposed on the etch stop layer; and a buried power rail embedded in the first dielectric layer, the etch stop layer, the trench isolation region, and the buried oxide layer. The buried power rail is isolated from the device layer through the buried oxide layer and trench-filling oxide in the trench isolation region.

### BACKGROUND OF THE INVENTION

### 1. Field of the Invention

The present invention relates to the field of semiconductor technology, and in particular, to an improved silicon-on-insulation (SOI) semiconductor structure and a manufacturing method thereof.

### 2. Description of the Prior Art

Backside Power Delivery (BPD) technology is one of the key technologies for realizing sub-3 nm node chip production. BPD eliminates the need for signal and power lines to compete for interconnect resources on the front side of the wafer. Instead, as the name suggests, power signals are transmitted from the backside of the wafer, leaving only signal transmission via front-side interconnects. BPD also allows for optimal manufacturing of these different metal layers, including wider lines for Vdd and Vss signal transmission and finer lines for carrying high-frequency signals. Despite these advantages, BPD still faces numerous process challenges that need to be overcome.

### SUMMARY OF THE INVENTION

It is one object of the present invention to provide an improved silicon-on-insulator (SOI) semiconductor structure and a manufacturing method thereof to solve the deficiencies or shortcomings of the existing technology.

One aspect of the invention provides a semiconductor structure including a silicon-on-insulator (SOI) substrate having a base substrate, a buried oxide layer on the base substrate, and a device layer on the buried oxide layer; a circuit element disposed on the device layer and surrounded by a trench isolation region in the SOI substrate; an etch stop layer disposed around the circuit element; a first dielectric layer disposed on the etch stop layer; and a buried power rail embedded in the first dielectric layer, the etch stop layer, the trench isolation region and the buried oxide layer. The buried power rail is isolated from the device layer by the buried oxide layer and a trench-filling oxide in the trench isolation region.

According to some embodiments, the buried power rail is electrically connected to a through substrate via in the base substrate.

According to some embodiments, the through substrate via is isolated from the base substrate by an oxide liner.

According to some embodiments, the through substrate via comprises a conductive layer.

According to some embodiments, the buried power rail comprises a work function metal layer and a bulk metal layer.

According to some embodiments, the conductive layer is in direct contact with the work function metal layer.

According to some embodiments, the conductive layer is in direct contact with the bulk metal layer.

According to some embodiments, the circuit element is a transistor, and wherein the transistor comprises a metal gate, and wherein the metal gate comprises the work function metal layer and the bulk metal layer.

According to some embodiments, a top surface of the metal gate, a top surface of the buried power rail, and a top surface of the first dielectric layer are coplanar.

According to some embodiments, the semiconductor structure further includes: a second dielectric layer covering the top surface of the first dielectric layer, the top surface of the metal gate, and the top surface of the buried power rail; and a local interconnect disposed in the second dielectric layer to electrically connect the buried power rail to a source/drain doping region of the transistor.

Another aspect of the invention provides a method for forming a semiconductor structure. A silicon-on-insulator (SOI) substrate is provided. The SOI substrate includes a base substrate, a buried oxide layer on the base substrate, and a device layer on the buried oxide layer. A circuit element is formed on the device layer. The circuit element is surrounded by a trench isolation region in the SOI substrate. An etch stop layer is formed around the circuit element. A first dielectric layer is formed on the etch stop layer. A buried power rail is formed in the first dielectric layer, the etch stop layer, the trench isolation region and the buried oxide layer. The buried power rail is isolated from the device layer by the buried oxide layer and a trench-filling oxide in the trench isolation region.

According to some embodiments, the buried power rail is electrically connected to a through substrate via in the base substrate.

According to some embodiments, the through substrate via is isolated from the base substrate by an oxide liner.

According to some embodiments, the through substrate via comprises a conductive layer.

According to some embodiments, the buried power rail comprises a work function metal layer and a bulk metal layer.

According to some embodiments, the conductive layer is in direct contact with the work function metal layer.

According to some embodiments, the conductive layer is in direct contact with the bulk metal layer.

According to some embodiments, the circuit element is a transistor, and wherein the transistor comprises a metal gate, and wherein the metal gate comprises the work function metal layer and the bulk metal layer.

According to some embodiments, a top surface of the metal gate, a top surface of the buried power rail, and a top surface of the first dielectric layer are coplanar.

According to some embodiments, the method further includes the steps of forming a second dielectric layer on the top surface of the first dielectric layer, the top surface of the metal gate, and the top surface of the buried power rail; and forming a local interconnect in the second dielectric layer to electrically connect the buried power rail to a source/drain doping region of the transistor.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 10 are schematic diagrams showing a method for forming a semiconductor structure according to an embodiment of the present invention.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

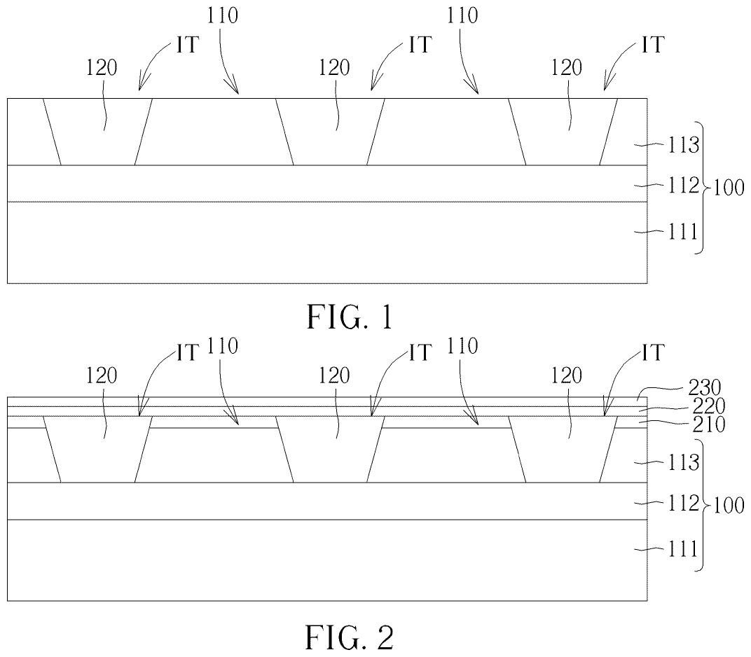

FIG. 1 to FIG. 10 are schematic diagrams showing a method for forming a semiconductor structure according to an embodiment of the present invention. As shown in FIG. 1, first, a silicon-on-insulator (SOI) substrate 100 is provided. The SOI substrate 100 includes a base substrate 111, a buried oxide layer 112 located on the base substrate 111, and a device layer 113 located on the buried oxide layer 112. According to an embodiment of the present invention, the base substrate 111 is, for example, a silicon substrate, and the thickness of the base substrate 111 is, for example, 7-100 micrometers. According to an embodiment of the present invention, the thickness of the buried oxide layer 112 is, for example, 2000 angstroms. According to an embodiment of the present invention, the device layer 113 is, for example, an epitaxial silicon layer, and the thickness of the device layer 113 is, for example, 1400 angstroms.

Subsequently, shallow trench isolation (STI) process is performed to form a trench isolation region IT and a plurality of active regions 110 surrounded and isolated by the trench isolation region IT in the device layer 113. According to an embodiment of the present invention, the trench isolation region IT includes a trench-filling oxide 120, such as, but not limited to, silicon dioxide.

As shown in FIG. 2, an oxidation process is then performed to form a gate oxide layer 210 on the active region 110. A deposition process, such as a chemical vapor deposition (CVD) process, is then performed to deposit a high dielectric constant (high-k) material layer 220 and a barrier layer 230 on the SOI substrate 100. According to an embodiment of the present invention, the high-k material layer 220 is, for example, but not limited to, HfO₂. According to an embodiment of the present invention, the barrier layer 230 is, for example, but not limited to, TiN.

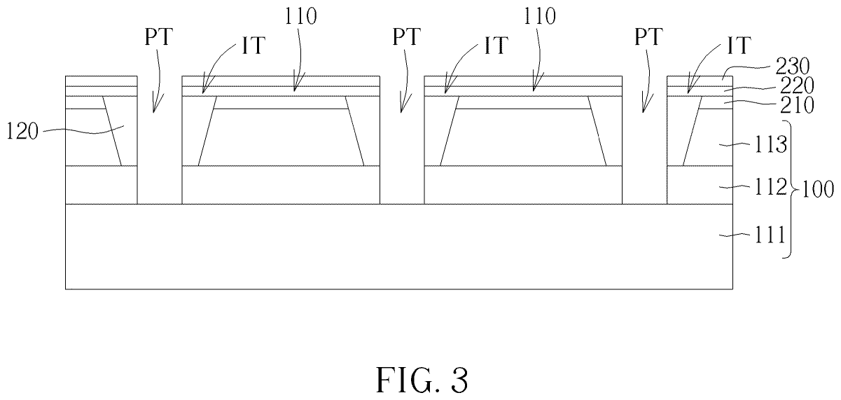

As shown in FIG. 3, a lithography process and an etching process are then performed to form a trench PT that penetrates the barrier layer 230, the high-k material layer 220, the trench-filling oxide 120, and the buried oxide layer 112. According to an embodiment of the present invention, the trench PT is located in the trench isolation region IT, and the bottom thereof exposes a portion of the base substrate 111.

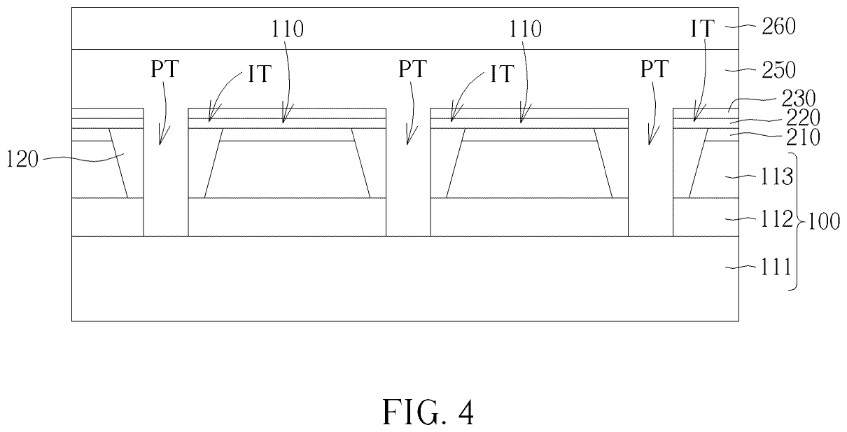

As shown in FIG. 4, a deposition process is then performed to deposit a polysilicon layer 250 on the SOI substrate 100, and the polysilicon layer 250 fills the trench PT. A deposition process, such as a chemical vapor deposition (CVD) process, is then performed to form a hard mask layer 260 on the polysilicon layer 250. According to an embodiment of the present invention, the hard mask layer 260 is, for example, but not limited to, a silicon nitride layer.

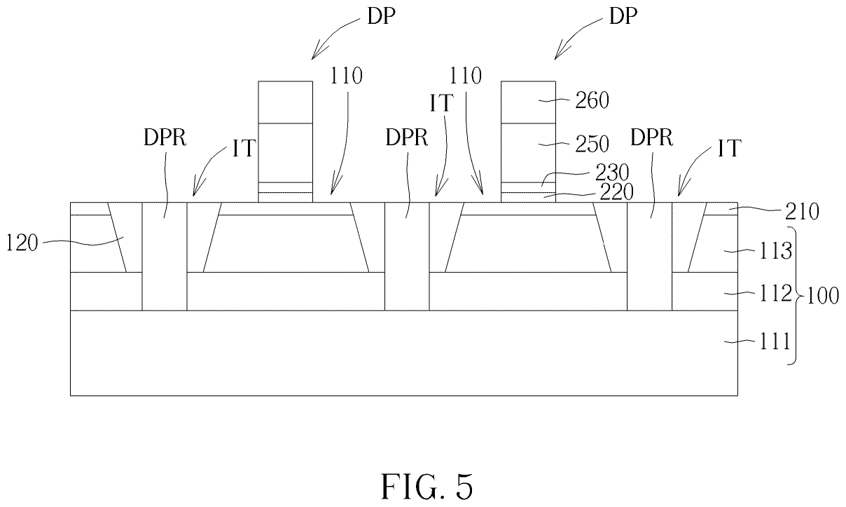

Subsequently, as shown in FIG. 5, a photolithography process and an etching process are performed to pattern the hard mask layer 260, the polysilicon layer 250, the barrier layer 230, and the high-k material layer 220 into a dummy gate structure DP, and simultaneously, a dummy polysilicon rail DPR is formed in the trench PT. According to an embodiment of the present invention, the dummy polysilicon rail DPR extends downward into the trench-filling oxide 120 and the buried oxide layer 112, and directly contacts the base substrate 111.

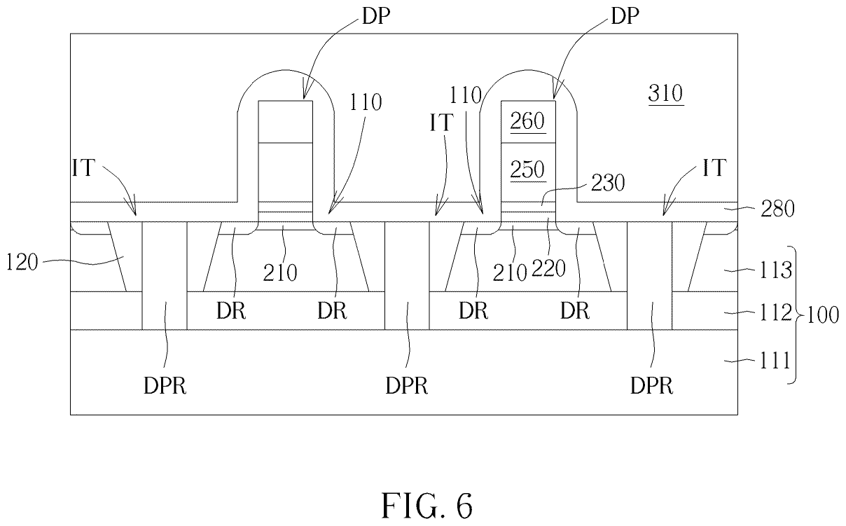

As shown in FIG. 6, an ion implantation process is performed to form a doped region DR within the active region 110. According to an embodiment of the present invention, the doped region DR may be, for example, an N-type or P-type doped region, and may serve as the source/drain doped region of a transistor. Subsequently, a deposition process, such as a chemical vapor deposition (CVD) process, is performed to deposit an etch stop layer 280, such as a silicon nitride layer, on the entire SOI substrate 100. According to an embodiment of the present invention, the etch stop layer 280 is conformally deposited on the trench isolation region IT, the dummy polysilicon rail DPR, and the dummy gate structure DP. A deposition process, such as a chemical vapor deposition (CVD) process, is then performed to deposit a dielectric layer 310 on the entire SOI substrate 100.

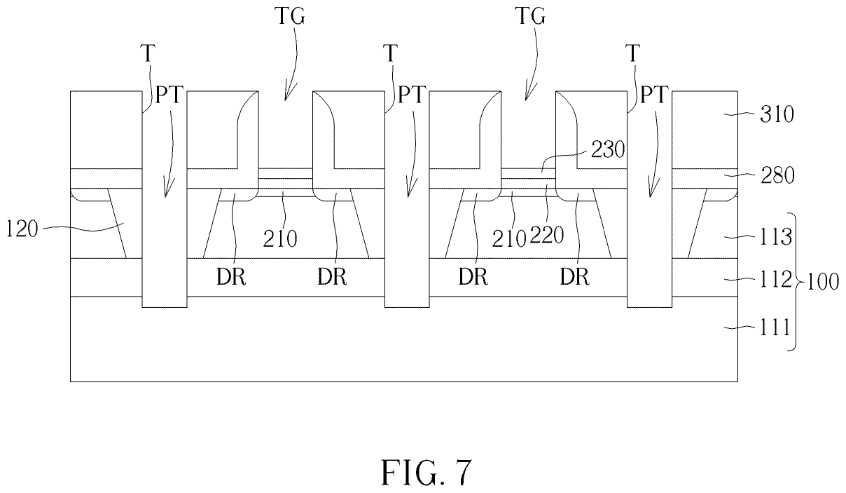

Subsequently, as shown in FIG. 7, a replacement metal gate (RMG) process is performed. For example, a chemical mechanical polishing (CMP) process is first performed to polish the dielectric layer 310 until the hard mask layer 260 is exposed. A lithography process and an etching process are then performed to form a trench T in the dielectric layer 310 and the etch stop layer 280, exposing the dummy polysilicon rail DPR. The dummy gate structure DP and the dummy polysilicon rail DPR are then removed together to form a gate trench TG and clear the trench PT.

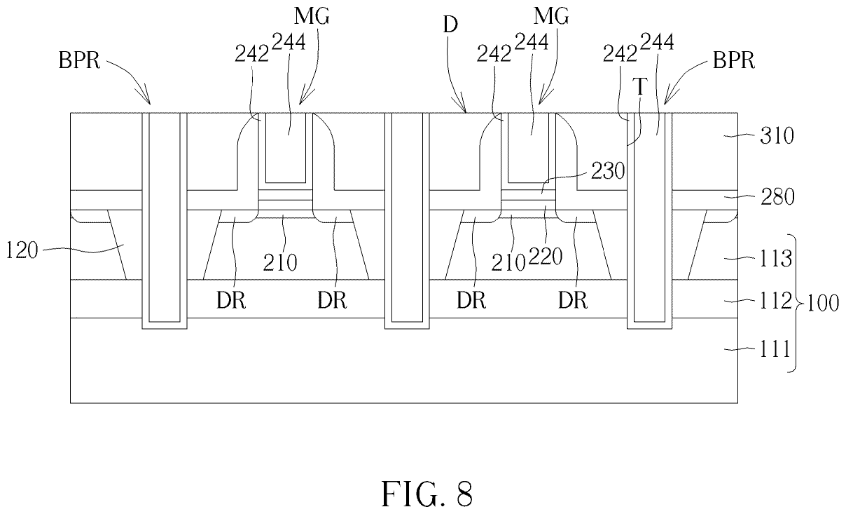

As shown in FIG. 8, a work function metal layer 242 and a bulk metal layer 244 are then deposited on the SOI substrate 100 in a blanket manner. A chemical mechanical polishing (CMP) process is then performed for planarization, thereby simultaneously forming a metal gate MG and a buried power rail BPR. The metal gate MG and the doped regions DR may constitute a circuit element D, such as a MOS transistor, wherein the doped region DR is a source/drain doped region. The buried power rail BPR includes the work function metal layer 242 and the bulk metal layer 244.

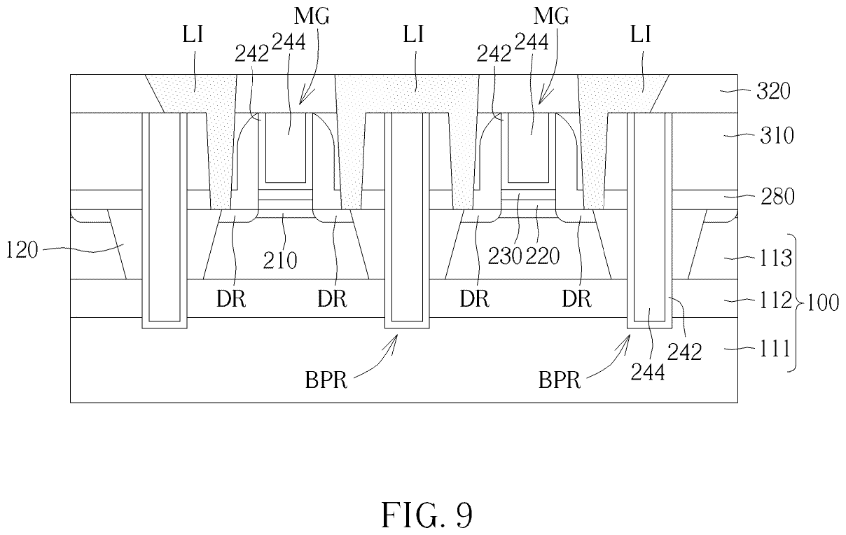

As shown in FIG. 9, a dielectric layer 320 is then deposited on the dielectric layer 310, the buried power rail BPR, and the metal gate MG. A metallization process is then performed to form an local interconnection LI in the dielectric layer 320 and the dielectric layer 310, which electrically connects the doped region DR and the buried power rail BPR. According to an embodiment of the present invention, the dielectric layer 310 and the dielectric layer 320 may be a single dielectric layer or a combination of multiple stacked dielectric layers.

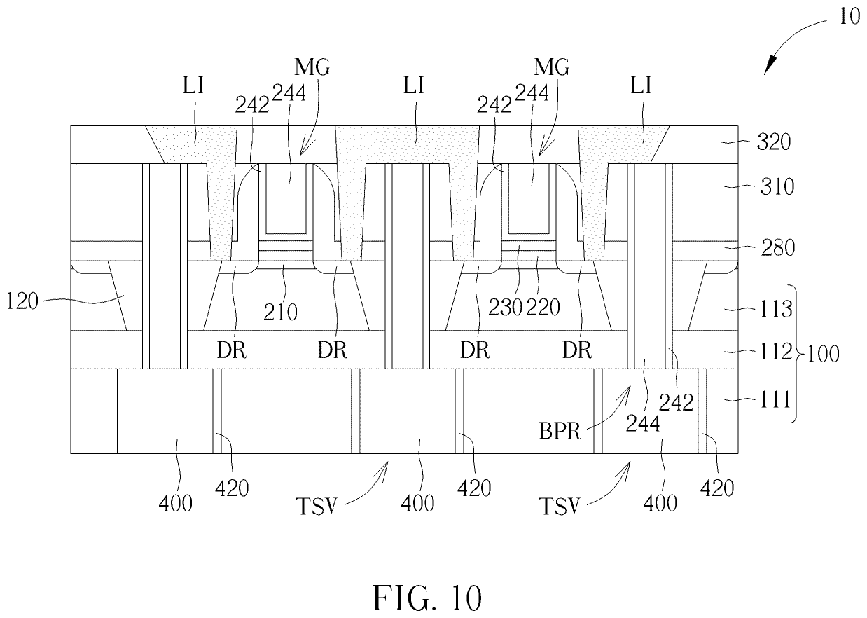

As shown in FIG. 10, a lithography process, an etching process, and a metallization process are then performed to form a through-silicon via (TSV) in the substrate 111, wherein the buried power rail BPR is electrically connected to the through-silicon via TSV in the base substrate 111. According to an embodiment of the present invention, the through-silicon via TSV includes a conductive layer 400, such as a copper layer. According to an embodiment of the present invention, the through-silicon via TSV is electrically isolated from the base substrate 111 by an oxide liner layer 420. According to an embodiment of the present invention, the conductive layer 400 of the through-silicon via TSV, such as a copper layer, is in direct contact with the work function metal layer 242. According to an embodiment of the present invention, the conductive layer 400 of the through-silicon via TSV, such as a copper layer, is in direct contact with the bulk metal layer 244.

Structurally, as shown in FIG. 10, the semiconductor structure 10 of the present invention includes a silicon-on-insulator (SOI) substrate 100, comprising a base substrate 111, a buried oxide layer 112 located on the base substrate 111, and a device layer 113 located on the buried oxide layer 112; a circuit element D, arranged on the device layer 113 and surrounded by a trench isolation region IT in the SOI substrate 100; an etch stop layer 280, disposed around the circuit element D; a dielectric layer 310, disposed on the etch stop layer 280; and a buried power rail BPR, embedded in the dielectric layer 310, the etch stop layer 280, the trench isolation region IT, and the buried oxide layer 112. The buried power rail BPR is isolated from the device layer 113 by a trench-filling oxide 120 in the buried oxide layer 112 and the trench isolation region IT.

According to an embodiment of the present invention, the buried power rail BPR is electrically connected to a through-silicon via (TSV) in the base substrate 111. According to an embodiment of the present invention, the through-silicon via TSV is isolated from the base substrate 111 by an oxide liner layer 420. According to an embodiment of the present invention, the through-silicon via TSV includes a conductive layer 400.

According to an embodiment of the present invention, the buried power rail BPR includes a work function metal layer 242 and a bulk metal layer 244. According to an embodiment of the present invention, the conductive layer 400 is in direct contact with the work function metal layer 242. According to an embodiment of the present invention, the conductive layer 400 is in direct contact with the bulk metal layer 244.

According to an embodiment of the present invention, the circuit element D is a transistor, including a metal gate MG. According to an embodiment of the present invention, the top surfaces of the metal gate MG, the buried power rail BPR, and the dielectric layer 310 are coplanar.

According to an embodiment of the present invention, the semiconductor structure 10 further includes: a dielectric layer 320, covering the top surface of the dielectric layer 310, the top surface of the metal gate MG, and the top surface of the buried power rail BPR; and a local interconnect LI, disposed in the dielectric layer 320, for electrically connecting the buried power rail BPR to a doped region DR (source/drain doped region) of the circuit element D (transistor). In some embodiments, the local interconnect LI may electrically connect the buried power rail BPR to the gate of the circuit element D (transistor).

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a silicon-on-insulator (SOI) substrate having a base substrate, a buried oxide layer on the base substrate, and a device layer on the buried oxide layer;
a circuit element disposed on the device layer and surrounded by a trench isolation region in the SOI substrate;
an etch stop layer disposed around the circuit element;
a first dielectric layer disposed on the etch stop layer; and
a buried power rail embedded in the first dielectric layer, the etch stop layer, the trench isolation region and the buried oxide layer, wherein the buried power rail is isolated from the device layer by the buried oxide layer and a trench-filling oxide in the trench isolation region.

2. The semiconductor structure according to claim 1, wherein the buried power rail is electrically connected to a through substrate via in the base substrate.

3. The semiconductor structure according to claim 2, wherein the through substrate via is isolated from the base substrate by an oxide liner.

4. The semiconductor structure according to claim 2, wherein the through substrate via comprises a conductive layer.

5. The semiconductor structure according to claim 4, wherein the buried power rail comprises a work function metal layer and a bulk metal layer.

6. The semiconductor structure according to claim 5, wherein the conductive layer is in direct contact with the work function metal layer.

7. The semiconductor structure according to claim 5, wherein the conductive layer is in direct contact with the bulk metal layer.

8. The semiconductor structure according to claim 5, wherein the circuit element is a transistor, and wherein the transistor comprises a metal gate, and wherein the metal gate comprises the work function metal layer and the bulk metal layer.

9. The semiconductor structure according to claim 8, wherein a top surface of the metal gate, a top surface of the buried power rail, and a top surface of the first dielectric layer are coplanar.

10. The semiconductor structure according to claim 9 further comprising:
a second dielectric layer covering the top surface of the first dielectric layer, the top surface of the metal gate, and the top surface of the buried power rail; and
a local interconnect disposed in the second dielectric layer to electrically connect the buried power rail to a source/drain doping region of the transistor.

11. A method for forming a semiconductor structure, comprising:
providing a silicon-on-insulator (SOI) substrate having a base substrate, a buried oxide layer on the base substrate, and a device layer on the buried oxide layer;
forming a circuit element on the device layer, wherein the circuit element is surrounded by a trench isolation region in the SOI substrate;
forming an etch stop layer around the circuit element;
forming a first dielectric layer on the etch stop layer; and
forming a buried power rail in the first dielectric layer, the etch stop layer, the trench isolation region and the buried oxide layer, wherein the buried power rail is isolated from the device layer by the buried oxide layer and a trench-filling oxide in the trench isolation region.

12. The method according to claim 11, wherein the buried power rail is electrically connected to a through substrate via in the base substrate.

13. The method according to claim 12, wherein the through substrate via is isolated from the base substrate by an oxide liner.

14. The method according to claim 12, wherein the through substrate via comprises a conductive layer.

15. The method according to claim 14, wherein the buried power rail comprises a work function metal layer and a bulk metal layer.

16. The method according to claim 15, wherein the conductive layer is in direct contact with the work function metal layer.

17. The method according to claim 15, wherein the conductive layer is in direct contact with the bulk metal layer.

18. The method according to claim 15, wherein the circuit element is a transistor, and wherein the transistor comprises a metal gate, and wherein the metal gate comprises the work function metal layer and the bulk metal layer.

19. The method according to claim 18, wherein a top surface of the metal gate, a top surface of the buried power rail, and a top surface of the first dielectric layer are coplanar.

20. The method according to claim 19 further comprising:
forming a second dielectric layer on the top surface of the first dielectric layer, the top surface of the metal gate, and the top surface of the buried power rail; and
forming a local interconnect in the second dielectric layer to electrically connect the buried power rail to a source/drain doping region of the transistor.
